(19) United States
(12) Patent Application Publication
(10) Pub. No.: US 2026/0059691 A1
(43) Pub. Date: Feb. 26, 2026

(54) MODULAR DATA CENTER WITH INTEGRATED TRANSFORMER

(71) Applicants: Sivan Sud, 133 Taconic Road, CT (US); Ryan Gordon, New Hartford, NY (US); John Cody Semones, Cottonwood Heights, UT (US)

(72) Inventors: Sivan Sud, 133 Taconic Road, CT (US); Ryan Gordon, New Hartford, NY (US); John Cody Semones, Cottonwood Heights, UT (US)

(73) Assignee: Cormint Data Systems, Inc., Fort Stockton, TX (US)

(21) Appl. No.: 18/815,525

(22) Filed: Aug. 26, 2024

(51) Int. Cl. H05K 7/14; H05K 7/20

(52) U.S. Cl. CPC H05K 7/1497; H05K 7/1492; H05K 7/20181; H05K 7/20745

(57) ABSTRACT

A modular data center comprising a transformer, a distribution panel, and data center components housed within a shipping container. The distribution panel is integrated into the low-voltage cabinet of the transformer, which minimizes the area of the container utilized by the transformer and distribution panel and maximizes the area of the container that can be utilized for the computer components of the data center.

### FIELD

The present invention relates to a modular data center that integrates a transformer to convert medium or high voltage down into voltage that can be distributed into computer servers.

### BACKGROUND

Deploying data centers is often done in rural areas, where renewable energy is plentiful, but labor is limited and expensive. The concrete required to support the transformer and the specialized labor required to terminate the electrical connections are significant cost drivers.

Moving data centers is common in flare gassing, where the gas source is finite. In this case, having an integrated transformer means quickly moving sites and does not require the additional costs and complexity associated with disconnecting and moving transformers and the associated support structures.

Mounting transformers into containers is not a new concept, however the combination of a medium or high power transformer, distribution components, and data center equipment into a single container has not occurred. The value of the container is largely driven by the amount of computing and power that it can house. Therefore, making the transformer and distribution panel as small as possible is crucial. This invention minimizes the area used by non-computer components by integrating the distribution panel into the low voltage cabinet of the transformer, effectively halving the size compared to traditional designs.

As can be seen, there is a need for a modular data center that includes all the necessary hardware for voltage transformation.

### BRIEF DESCRIPTION OF THE DRAWINGS

FIG. 1 is a perspective view of a shipping container according to an embodiment of the present invention showing fans, server racks, exhaust, filtration, mains distribution panel, busduct and transformer with the roof hidden for visibility into the container.

FIG. 2 is a perspective view of a shipping container according to an embodiment of the present invention showing fans, server racks, exhaust, filtration, mains distribution panel, busduct and transformer.

### DETAILED DESCRIPTION

Embodiments of the present invention are further described in detail below with reference to the accompanying drawings and embodiments. The following examples are intended to illustrate the invention, but are not intended to limit the scope of the invention.

A general overview of the various features of the invention will be provided, with a detailed description following. Broadly, an embodiment of the present invention provides a modular data center with integrated transformer.

As used herein, “low-voltage” is defined to be 1000 volts or less, “medium-voltage” is greater than 1,000 volts (1 kV) and less than 100,000 V (100 kV), and “high-voltage” is greater than 100,000 V (100 kV) up to 230,000 V (230 kV) in accordance with the ANSI C84.1 standards.

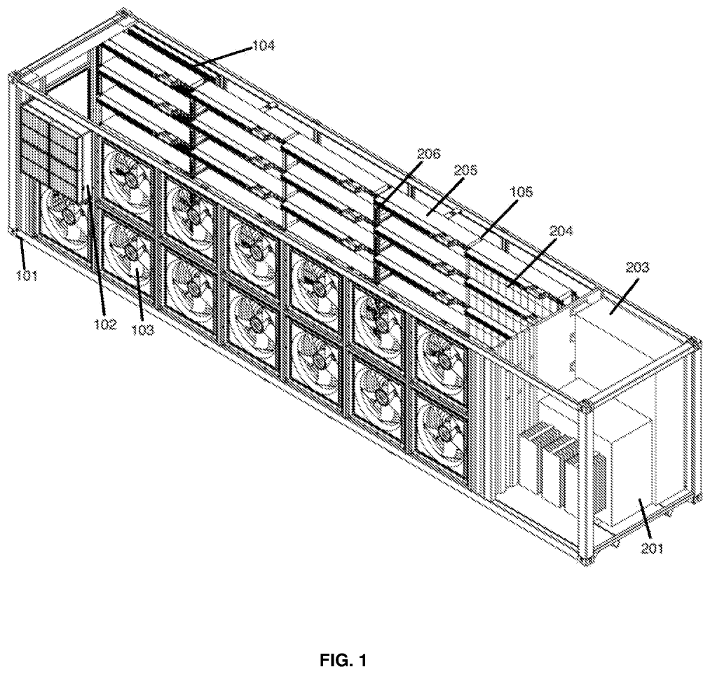

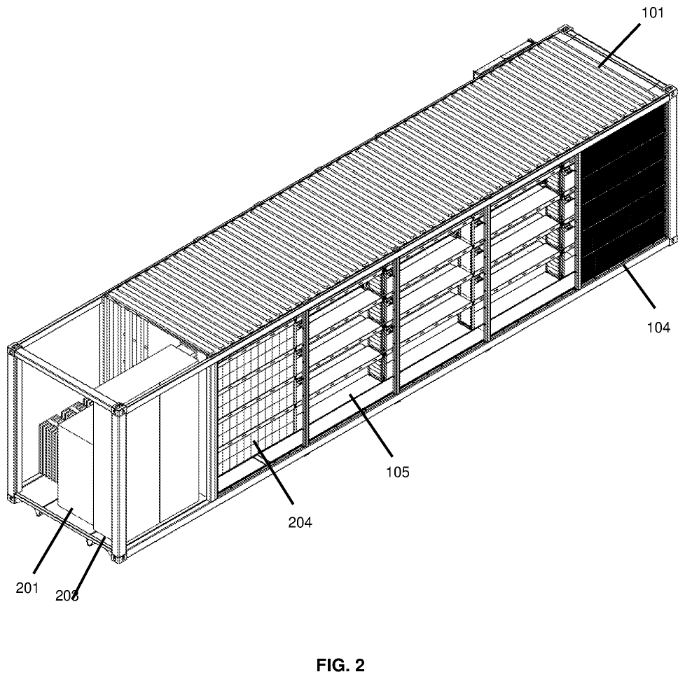

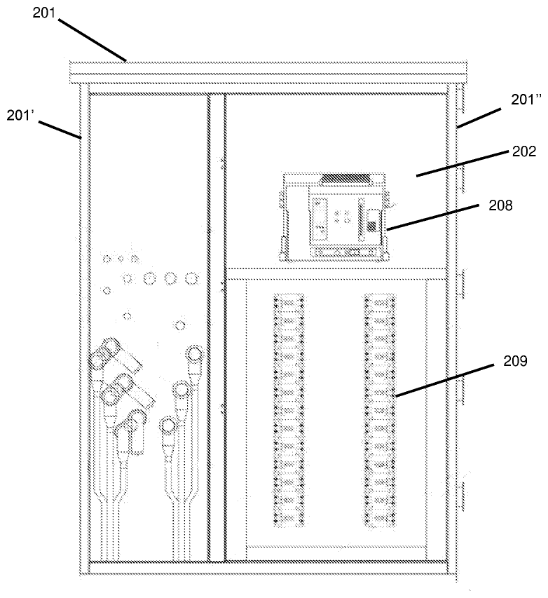

FIGS. 1 and 2 depict a modular data center 100 according to embodiments of the present disclosure. The modular data center 100 may be housed within a shipping container 101. The shipping container 101 may include a transformer 201 with built in distribution panel 202, air filters 102, fans 103, ventilation panels 104, computer racks 105, and low voltage power distribution units 203 within the interior of the shipping container 101. Computers 204 may be installed on racks 105 within the interior of the shipping container 101. The computers 204 may be computer servers or other data processing equipment. For example, the computers 204 may be central processing units (CPU), graphics processing units (GPU), application-specific integrated circuits (ASIC), field-programmable gate arrays (FPGA), or the like.

The transformer 201 may receive power at medium voltage from an external source (not shown), such as a utility grid, substation transformer, or a generator, and transform the power to a low voltage that can be used by computers. The transformer 201 may be an oil filled transformer, dry transformer, or silicone transformer, but is preferably an oil-filled transformer. The main distribution panel 202 may include the main circuit breaker 208 and may further include all of the branch circuit breakers 209 for the power distribution units 203, enabling safe operation that meets electrical code. Power may be provided from the distribution panel 202 to the low-voltage power distribution units 203.

The transformer 201 may comprise a first cabinet and a second cabinet 201″. Conventionally, the first cabinet 201′is typically utilized as a medium-voltage cabinet, and the second cabinet 201″ is typically utilized as a low-voltage cabinet which contains taps for terminating wires and/or bus ducts. According to embodiments of the present disclosure, the first cabinet 201′may be utilized as a medium-voltage cabinet and a second cabinet 201″ may be further utilized to house distribution panel 202 which is integrated into the transformer.

The transformer 201 with integrated distribution panel 202 may be compact, and is preferably as small as possible, to minimize the amount of space taken up by the transformer components and maximize the amount of space available to be utilized for the computers and computing-related components of the data center. Preferably, the transformer 201 with integrated distribution panel 202 may be about one half of the size compared to conventional designs with a separate transformer and distribution panel. For example, the amount of space utilized for a conventional design from about 400-500 cm may be reduced to about 150-250 cm for the transformer 201 with integrated distribution panel 202.

The shipping container 101 may be an intermodal shipping container, which may be designed to comply with the standards set forth in the International Organization for Standardization (ISO) and the Convention for Safe Containers (CSC) to receive CSC certification. The shipping container 101 may include structures for mounting the air filters 102, fans 103, and ventilation panels 104, and an access door for providing access to the interior of the shipping container 101. The shipping container 101 may be reinforced in areas with high load, such as, for example, a side or end on which the transformer 201 is located.

The computers 204 that are placed on the racks 105 may be cooled utilizing fans 103, which may be intake fans. Air filters 102 may be installed on an intake side of the container 101 and ventilation panels may be installed on an exhaust side of the container 101. While one air filter 102 is depicted in FIG. 1 in order to show the location of the fans 103, it is contemplated that air filters 102 may be installed on the exterior side of each of the fans 103. The ventilation panels 104 may, for example, be exhaust louvers or honeycomb vents, which may provide rain ingress protection. The air flows through the filters 102 on the intake side, through the fans 103, through the computers 204, and gets exhausted through the ventilation panels 104 on the exhaust side.

The computers 204 may receive low-voltage power from the power distribution units 203 that are installed on the racks 105. Power distribution unit cables may run through the shelf cross-members 205 of the racks 105, which serve as raceways that have venting, enabling active cooling from the fans 103 placed along the wall on the intake side of the container 101. These cables then enter the main distribution panel 202 within the low-voltage cabinet of the transformer 201.

Networking switches may be mounted on vertical members 206 of the racks 105, and may also be cooled by the fans 103. The networking switches may be in close proximity to the computers 204, reducing the signal degradation and cost of the networking cables.

The above description is only to example embodiments of the present invention and it should be noted that those skilled in the art can make improvements and modifications without departing from the technical principles of the present invention and as such, variations are also considered to be the scope of protection of the present invention.

What is claimed is:

1. A modular data center comprising:
a certified shipping container, the shipping container including mounting features for fans, air filters, and ventilation panels;
one or more racks within an interior of the shipping container which are configured to hold a plurality of computers and networking switches;
a transformer within an interior of the shipping container which is configured to receive power from an external source, the transformer including an integrated distribution panel having main circuit breaker and branch circuit breakers; and
low-voltage power distribution units which are configured to supply low-voltage power from the distribution unit of the transformer to the plurality of computers and networking switches on the racks.

2. The modular data center of claim 1, wherein the transformer includes first and second cabinets, and wherein the first cabinet is a medium-voltage cabinet and the integrated distribution panel is disposed within the second cabinet.

3. The modular data center of claim 1, wherein the transformer is configured to receive medium-voltage power from an external source and step down the power to low-voltage power.

4. The modular data center of claim 1, wherein the shipping container is reinforced for additional weight at a location where a transformer is installed.

5. The modular data center of claim 1, further comprising intake fans installed along an intake side wall of the shipping container, the fans configured to draw exterior air from through the intake side wall, which flows through the racks to cool the plurality of computers and networking switches, and is exhausted at an exhaust side wall of the shipping container.

6. The modular data center of claim 1, further comprising air filters mounted along an exterior side of the intake side wall of the shipping container.

7. The modular data center of claim 1, ventilation panels mounted along an exterior side of the exhaust side wall of the shipping container.
